(19) United States
(12) Patent Application Publication
(10) Pub. No.: US 2014/0284714 A1
(43) Pub. Date: Sep. 25, 2014

(54) SEMICONDUCTOR DEVICE

(71) Applicant: Hitachi, Ltd., Tokyo (JP)

(72) Inventors: Kenji Miyakoshi, Tokyo (JP); Youhei Yanagida, Tokyo (JP); Hiroki Kimura, Tokyo (JP); Takayuki Ooshima, Tokyo (JP)

(21) Appl. No.: 14/192,775

(22) Filed: Feb. 27, 2014

(30) Foreign Application Priority Data
Mar. 22, 2013 (JP) 2013-059285

(51) Int. Cl. H01L 29/78

(52) U.S. Cl. CPC H01L 29/7816
USPC 257/337

(57) ABSTRACT

Disclosed is a semiconductor device that includes a first MOS transistor having a predetermined size and a second MOS transistor having a lager size than the first MOS transistor. The first MOS transistor is divided into two or more sections, each paired with a corresponding section of the second MOS transistor to form a unit cell. As the unit cell is cyclically formed on a substrate, the current mirror ratio between the total size of the first MOS transistor and the total size of the second MOS transistor remains unaffected by the nonuniformity of position-dependent temperature distribution.

### CROSS-REFERENCE TO RELATED APPLICATION

This application claims the priority of Japanese Patent Application No. 2013-059285 filed Mar. 22, 2013, which is incorporated herein by reference in its entirety.

### BACKGROUND

The present invention relates to a semiconductor device. More specifically, the present invention relates to a semiconductor device having a MOS transistor in the field of analog LSI technology, to a method of manufacturing a semiconductor device having a MOS transistor that is required to be relatively accurate, and to a variation reduction layout structure of a current mirror circuit.

In a current mirror circuit used in an analog circuit, it is generally demanded that the electrical characteristics of elements of the current mirror circuit exhibit small relative variation. Further, in the field of a power IC, it is demanded that enhanced control be exercised because the heat generation effect of the IC is a cause of variation.

In a driver IC 201 depicted in FIG. 2, for example, control is exercised over an external load 204 that causes a current of several hundred milliamperes to several amperes to flow to an external power supply 203 ranging from several tens to several hundreds of volts. The current of the external load 204 is controlled by a main MOS transistor 206.

In order to minimize an IC loss, the current value 208 (Im) of the driver IC 201 is detected, by a current detection circuit 205, in accordance with the current value 209 (Is) of a sense MOS transistor 207 and controlled by an external controller IC 202.

The current ratio (Is/Im) between the sense MOS transistor 207 and the main MOS transistor 206 is substantially set to be between 1:100 and 1:1000. This current ratio is substantially equal to the area ratio between the transistors 207, 206.

Further, as the current 208 flowing in the main MOS transistor 206 is much larger than a current flowing, for instance, in a digital circuit, the area of the driver IC 201 is mostly occupied by the main MOS transistor 206.

The accuracy of the current value 208 of the main MOS transistor 206, which determines the performance of the driver IC 201, is directly affected by the variation in the current ratio (Is/Im) between the current value 208 of the main MOS transistor 206 and the current value 209 of the sense MOS transistor 207. It is therefore demanded that relative variations and relative changes in the two MOS transistors 206, 207 be minimized.

Causes of relative variations in the above-mentioned MOS transistors used for power ICs are described below in comparison with relative variation in a common low-voltage MOS transistor operating, for instance, at a power supply voltage of 5 V or lower.
(1) Firstly, an oxide film thickness, an ion injection amount, a photolithography line width, an etching line width, and the like randomly vary at a local part in a wafer plane due to manufacturing process fluctuation. The amounts of such variations randomly change. Therefore, when the area of an element to be compared increases, the variations are compensated for.

The above is known as the so-called Pelgrom plot (refer to “Matching properties of MOS transistors” written by M. Pelgrom, A. Duinmaijer, and A. Welbers (IEEE Journal of Solid-State Circuits, Vol. 24, No. 5, pp. 1433-1439, October 1989)). According to the Pelgrom plot, the amount of variation is proportional to the reciprocal of the square root of the area of the element.

As regards the relative variations in the above-mentioned MOS transistors used for power ICs, the area of the main MOS transistor is sufficiently large. Therefore, the variation in the current ratio is determined by the area of the sense MOS transistor.
(2) Secondly, the ion injection amount, a grinding amount, the film thickness, an annealing temperature, and the like in a semiconductor manufacturing process exhibit variations in a semiconductor wafer plane due to a semiconductor manufacturing machine. The cycle lengths of such changes are substantially equal to or greater than the chip size of the ICs. In a common current mirror circuit, the MOS transistors to be compared are smaller in area than the IC chip size. Therefore, the amounts of such changes do not significantly contribute to the relative variations.

However, the area of the above-mentioned power ICs is mostly occupied by the main MOS transistor. In other words, the power ICs have substantially the same size as the main MOS transistor. Therefore, the main MOS transistor significantly contributes to the variations.
(3) Thirdly, the photolithography line width, the etching line width, and the like in the manufacturing process change depending on the arrangement and pattern density of the targeted MOS transistor and elements around it. Further, stress distribution also changes depending on a pattern. Therefore, mobility is affected as well.
(4) Fourthly, the variations are caused by self-heating of the ICs when they are driven. When an employed power IC generates a large amount of heat, the temperature distribution in a chip plane has a gradient. Therefore, even when the MOS transistors have the same configuration, different current characteristics result. In this document, the difference in current with respect to such temperature changes is also referred to as a variation.

As the regards the local fluctuation in the manufacturing process, which is mentioned firstly, the amount of variation may be decreased by increasing the area of the MOS transistors. However, a trade-off arises with respect to the cost of a chip. Therefore, the degree of freedom in IC design is low.

As regards the comprehensive changes in the manufacturing process, which is mentioned secondly, the use of a common-centroid layout is effective (refer to Japanese Patent No. 3179424). When the common-centroid layout is used, the two MOS transistors to be compared have the same center of gravity when they are disposed.

As regards the variation caused by an arrangement pattern, which is mentioned thirdly, the disposition of a dummy cell and the use of a common diffusion layer or the like are effective (refer to the disclosure in Japanese Unexamined Patent Application Publication No. 2010-27842).

### SUMMARY

Even when the first to third conventional measures against variations ((1) to (3) above) are taken in relation to a circuit applicable to the present invention, the fourth variation, that is, the temperature variation, occurs significantly. Thus, the accuracy of a control IC is low.

FIG. 3 is a schematic diagram illustrating functional regions in a chip plane of a driver IC having a conventional structure.

A main MOS transistor region 302, a sense MOS transistor region 303, a control circuit region 304 of the driver IC 301 are depicted in FIG. 3. FIG. 3 illustrates the areas occupied by the individual regions and their positions. The common-centroid layout is employed for the sense MOS transistor region 303 in order to reduce the comprehensive variation in the manufacturing process so that the sense MOS transistor region 303 is positioned at the center of the main MOS transistor region 302.

FIG. 4 illustrates the channel temperature (silicon diffusion layer temperature) of the MOS transistors at a cross-section 305 of the driver IC 301. The temperature distribution prevailing when the package temperature of the driver IC is equal to room temperature is indicated as a characteristic curve 401. The temperature distribution prevailing when the package temperature of the driver IC is equal to the specified maximum temperature is indicated as a characteristic curve 402.

Here, it is assumed that the package temperature is sufficiently heat-exchanged with an external environment and maintained constant without regard to an IC operation. The channel temperature rises from a package boundary face (the outermost circumference of the IC) toward the center. The characteristic curves 401, 402, which differ in the IC package temperature, also differ in the rate of temperature rise at the center. The reason is that the higher the chip temperature, the lower the possibility of heat dissipation. FIG. 5 illustrates how the difference in channel temperature distribution affects the control performance of the driver IC.

The vertical axis of FIG. 5 indicates the Ratio, that is, the current ratio (current mirror ratio) between the main MOS transistor and the sense MOS transistor, and the horizontal axis indicates the package temperature.

In this document, the Ratio is defined as the value obtained when the current of the main MOS transistor is divided by the current of the sense MOS transistor.

The variation in the Ratio (or the temperature fluctuation), that is, the ΔRatio, is a main factor that determines the control accuracy of the IC covered by this document.

As indicated by FIG. 4, the higher the package temperature, the higher the temperature of the center of the IC as compared to the temperature of the outer circumference of the IC. The current of the MOS transistors decreases with an increase in temperature. Therefore, when the package temperature rises, the current value of the sense MOS transistor becomes relatively smaller than the current value of the main MOS transistor. This causes the Ratio to change.

It is demanded that the driver IC deliver constant performance within an operating temperature range. Therefore, it is demanded that the ΔRatio be tolerated as a variation. Hence, the task to be achieved by an IC to be covered by the present invention is to minimize the ΔRatio. FIG. 6 illustrates a conventional plan layout that includes main MOS transistors and a sense MOS transistor. The sense MOS transistor 603 is disposed at the center of the IC 601. The main MOS transistors 609-632 are disposed on the periphery of the sense MOS transistor 603. FIG. 10 illustrates electrical connections for the IC 601 depicted in FIG. 6.

In, the plan layout of a semiconductor device provided by the present invention is such that a main MOS transistor element section is paired with a sense MOS transistor element section, and that the pair of the main and sense MOS transistor element sections is cyclically disposed. Two or more main MOS transistor element sections and two or more sense MOS transistor element sections are electrically connected in parallel while source, drain, and gate electrode terminals are shared. Hence, the total gate length of a main MOS transistor element formed of the two or more main MOS transistor element sections is the sum of the gate lengths of the individual main MOS transistor element sections. Similarly, the total gate length of a sense MOS transistor element formed of the two or more sense MOS transistor element sections is the sum of the gate lengths of the individual sense MOS transistor element sections.

To be precise, the above-mentioned gate length is not an actual dimension, but an effective size based on electrical characteristics.

Using the above-described configuration makes it possible to obtain a semiconductor device that provides constant relative temperature dependence of accuracy when uneven temperature distribution occurs in the plane of circuitry due to self-heating of a main MOS transistor and of a sense MOS transistor.

Further, an advantageous effect of the present invention may be maximized by dividing a sense MOS transistor element and a main MOS transistor element by the number of divisions that is determined by the minimum permissible gate length of the sense MOS transistor element sections.

The minimum permissible gate length is a minimum gate length that maintains MOS transistor characteristics determined by limitations imposed on a manufacturing process. Let us assume, for example, that the total gate length of a sense MOS transistor element is Ws, and that the minimum size of a sensor MOS transistor element section is Wm, and further that the number of divisions is X. If the following equation is established when the number of divisions is X, the sense MOS transistor element is distributed in the most unbiased manner in the plane of circuitry while the minimum permissible gate size is employed:

Wm≦Ws/X<2×Wm.

Further, in order to minimize the cost of manufacture, it is preferred that the distance between individual element sections be minimized within the limits imposed on the manufacturing process. In other words, it is preferred that the individual element sections be positioned nearest to each other.

It is also preferred that the main MOS transistor element and the sense MOS transistor element have the same center of gravity when they are laid out.

The present invention produces a great advantageous effect particularly when it is applied to an LDMOS transistor that is prepared on an SOI substrate and isolated by an embedded oxide film.

As described above, the present invention makes it possible to easily obtain a semiconductor device having a MOS transistor that acts as a power IC generating a large amount of heat by itself and is expected to exhibit relative accuracy.

### BRIEF DESCRIPTION OF THE DRAWINGS

Embodiments of the present invention will be described in detail based on the following figures, in which:

FIG. 1 is a diagram illustrating how to implement a semiconductor device according to a first embodiment of the present invention;

FIG. 2 is a diagram illustrating an example of a driver IC that uses a current mirror circuit;

FIG. 3 is a diagram illustrating the areas occupied by and the positions of a sense MOS transistor and a main MOS transistor, which are included in the driver IC;

FIG. 4 is a diagram illustrating the channel temperatures of the MOS transistors at a cross-section depicted in FIG. 3;

FIG. 5 is a diagram illustrating the package temperature dependence of a current mirror ratio of the IC depicted in FIG. 3;

FIG. 6 is a diagram illustrating the planar layout of a conventional semiconductor device;

FIG. 7 is a cross-sectional view of a representative one of the element sections that form a circuit element depicted in FIGS. 1 and 6;

FIG. 8 is a diagram illustrating how to implement the semiconductor device according to a second embodiment of the present invention;

FIG. 9 is a diagram illustrating electrical connections for the elements depicted in FIGS. 1 and 8; and

FIG. 10 is a diagram illustrating electrical connections for the elements depicted in FIG. 6.

### DETAILED DESCRIPTION

### First Embodiment

FIG. 6 is a diagram illustrating the planar layout of a conventional semiconductor device.

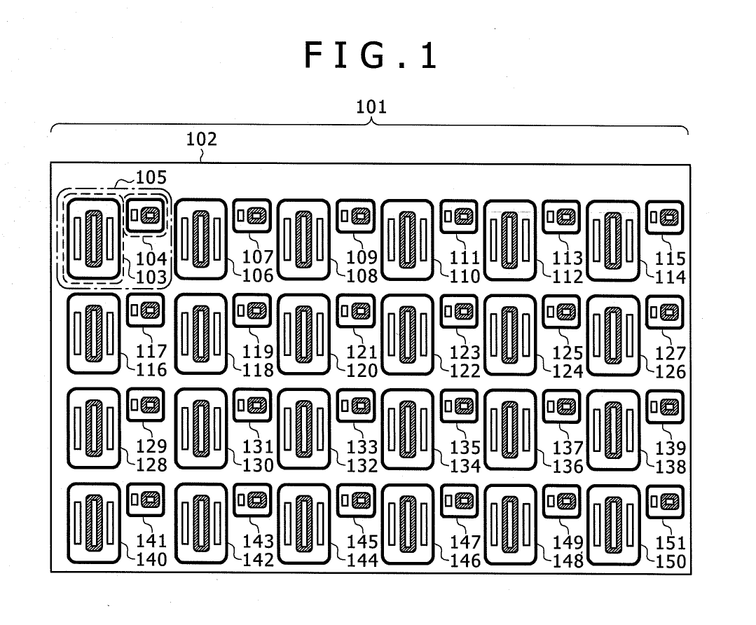

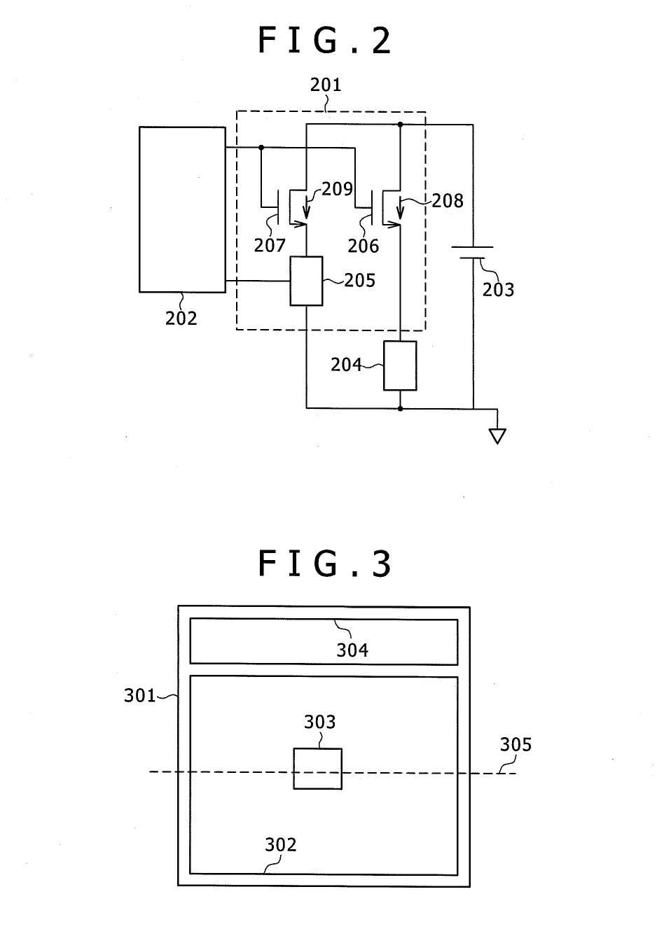

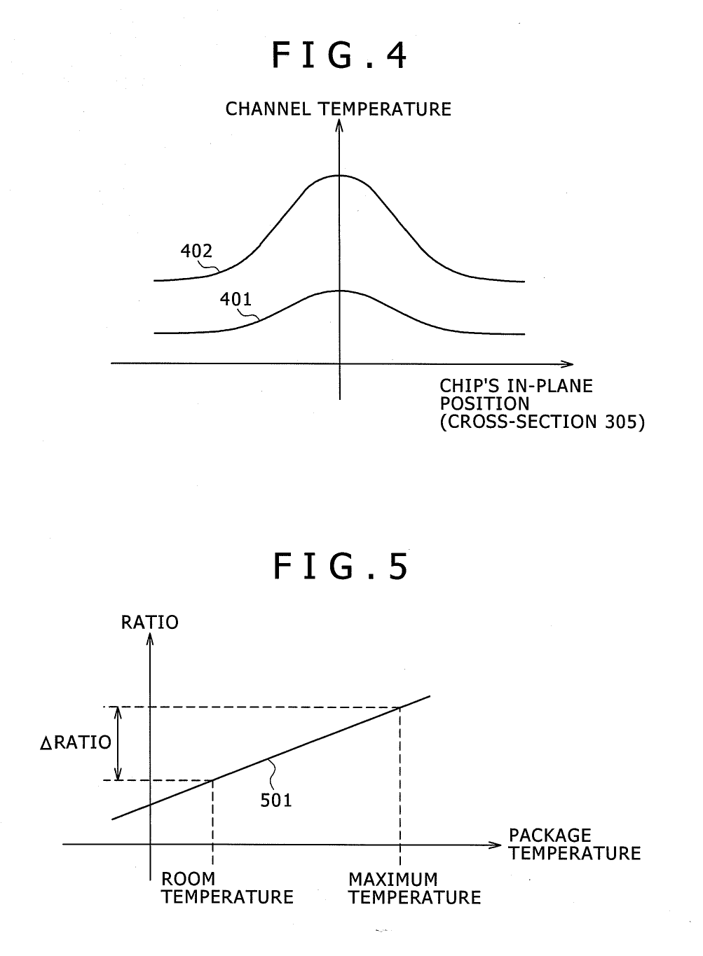

FIG. 1 is a diagram illustrating the planar layout of a semiconductor device according to a first embodiment of the present invention.

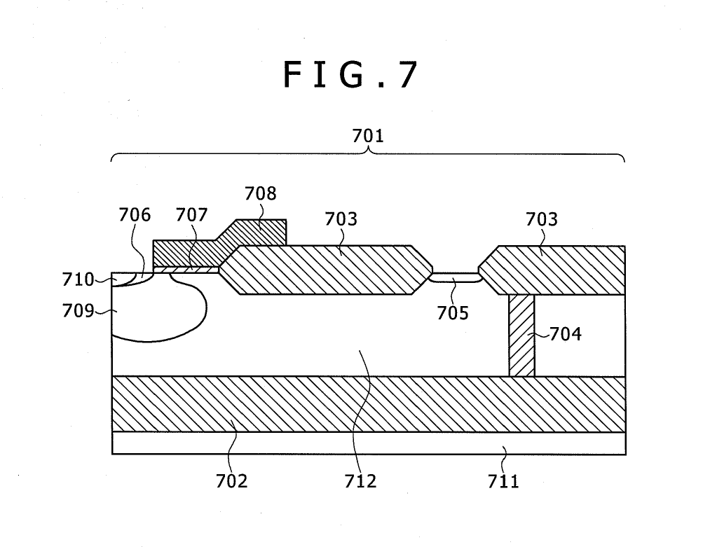

FIG. 7 is a cross-sectional view of a representative element section of the semiconductor devices depicted in FIGS. 1 and 6.

First of all, an embodiment of the conventional semiconductor device will be described. The first embodiment will be described later.

The conventional semiconductor device 601 depicted in FIG. 6 includes twenty-five LDMOS transistors, which are formed on a part of a silicon substrate 602 and indicated at 603 and 604.

The LDMOS transistors 603, 604 are identical with “MOS transistor elements” described in conjunction with the present invention.

The reference numeral 603 denotes a sense MOS transistor element. The reference numeral 604 denotes a main MOS transistor element.

Referring to FIG. 6, the sense MOS transistor element 603 includes one sense MOS transistor section, and the main MOS transistor element 604 includes twenty-four main MOS transistor element sections 609-632.

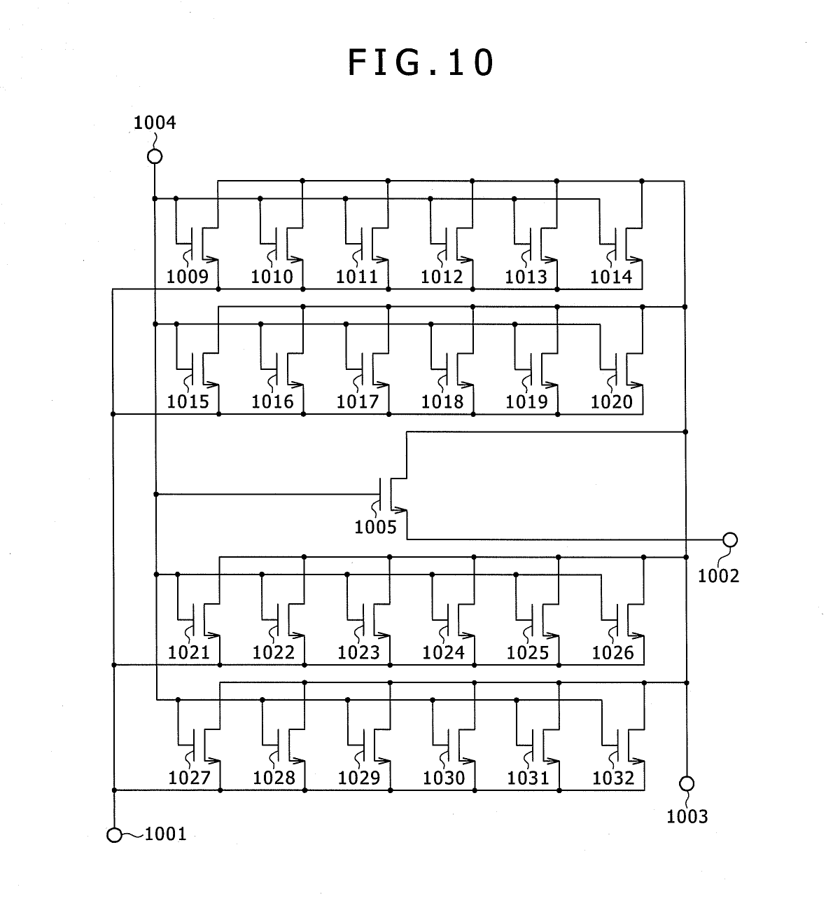

The individual MOS transistor element sections in the sense MOS transistor element 603 and main MOS transistor element 604 are configured so that their gate, source, and drain terminals are electrically connected in parallel. As an example, the drain terminal is made common as depicted in FIG. 10 while the source terminal is branched by the main MOS transistor element and sense MOS transistor section. An alternative connection scheme may be employed depending on the situation so that the source terminal is made common while the drain terminal is branched by the main MOS transistor element and sense MOS transistor section.

The drain current ratio between the sense MOS transistor element 603 and the main MOS transistor element 604 is referred to as the current mirror ratio.

The number of LDMOS transistors formed of the main MOS transistor element 604 and sense MOS transistor element 603 is indicated as an example. In reality, the number of LDMOS transistors varies with a demanded current mirror ratio. The actually used current mirror ratio substantially ranges from 1:100 to 1:1000.

An LDMOS transistor that forms each transistor section is insulated and isolated by an isolating oxide film 607 and provided with a drain section 605 and a source section 606. The cross-sectional structure of the LDMOS transistor is depicted in FIG. 7, which is a cross-sectional view taken along line 608 of FIG. 6.

Referring to FIG. 7, which illustrates the cross-sectional structure of the LDMOS transistor 701, the LDMOS transistor 701 is formed on an SOI substrate 711 and electrically isolated from the other LDMOS transistors by insulating oxide films 702, 703, 704.

The conductivity type of the LDMOS transistor 701 may be either N-type or P-type. Here, it is assumed that an N-type LDMOS transistor is used. In a region of the above-mentioned isolated SOI substrate, a low-concentration N-type drift layer 712, an N-type drain layer 705, and a source layer 706 are formed. A body layer 709 and a contact layer 710 for the body layer 709 are also formed. The body layer 709 is formed by using a gate oxide film 707 and a polysilicon cap film 708 as a photomask. The concentration of the drift layer 712 and body layer 709 may be adjusted to exhibit a high breakdown voltage so that even when a high voltage is applied to the drain layer 705 and source layer 706, the resulting electric field does not concentrate on the drift layer 712 and body layer 709, but is uniformly distributed between the drain and source. The LDMOS transistor 701 represents an exemplary configuration provided by the present invention. The present invention is not limited to the structure of the LDMOS transistor 701.

In the example of a conventional structure depicted in FIG. 6, the sense MOS transistor element 603 is disposed at one place or at two to four separate places. The reason is that when the sense MOS transistor element 603 is concentrated at one place, high area efficiency is achieved because the area surrounding the LDMOS transistor formed of the sense MOS transistor element 603 is large. Further, variation due to a manufacturing process may be reduced if the main MOS transistor element 604 has the same center of gravity as the sense MOS transistor element 603 when they are laid out.

Meanwhile, in the first embodiment of the present invention, a sense MOS transistor element section 103 is divided wherever possible as depicted in FIG. 1 to form a unit cell 105 together with a main MOS transistor element section 104. Further, the resulting unit cell 105 is repeatedly disposed to form a semiconductor device 101. When the sense MOS transistor element section 103 is divided wherever possible, the resulting size is, for example, the minimum size permitted by an offered process.

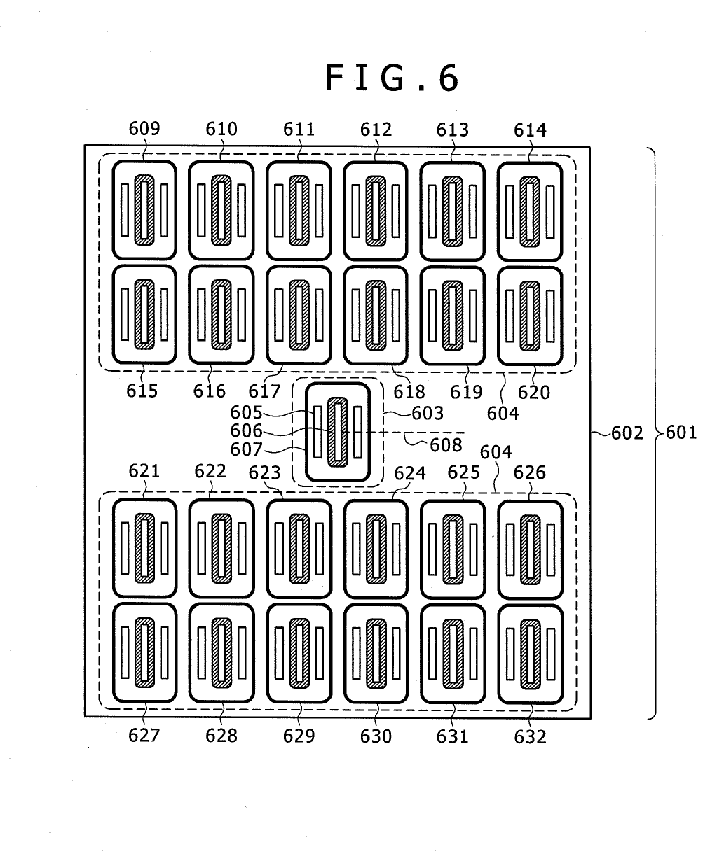

The first embodiment is configured so that the sense MOS transistor and the main MOS transistor are uniformly distributed in an IC chip. Therefore, even when a temperature gradient depicted in FIG. 5 exists, the Ratio (current mirror ratio) between the sense MOS transistor and the main MOS transistor comes close to being constant irrespective of temperature.

In other words, when the graph of FIG. 5 is prepared, the slope of the straight line in the graph comes close to 0 (zero). It is preferred that the distance between the sense and main MOS transistor sections disposed in the unit cell 105 be minimized. In FIG. 1, the drain terminal of the sense MOS transistor section is reduced to half size and disposed in the direction of source and drain. However, the present invention is not limited to such a configuration.

### Second Embodiment

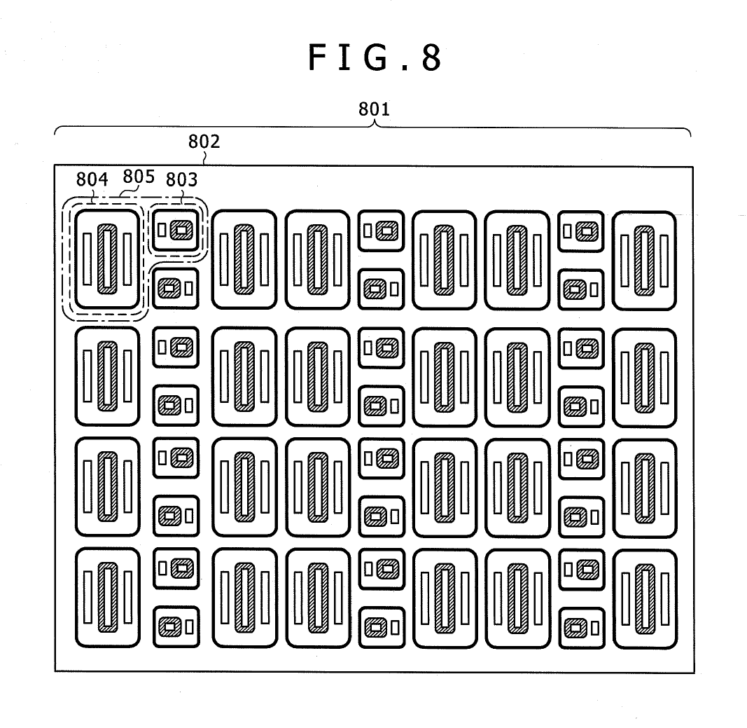

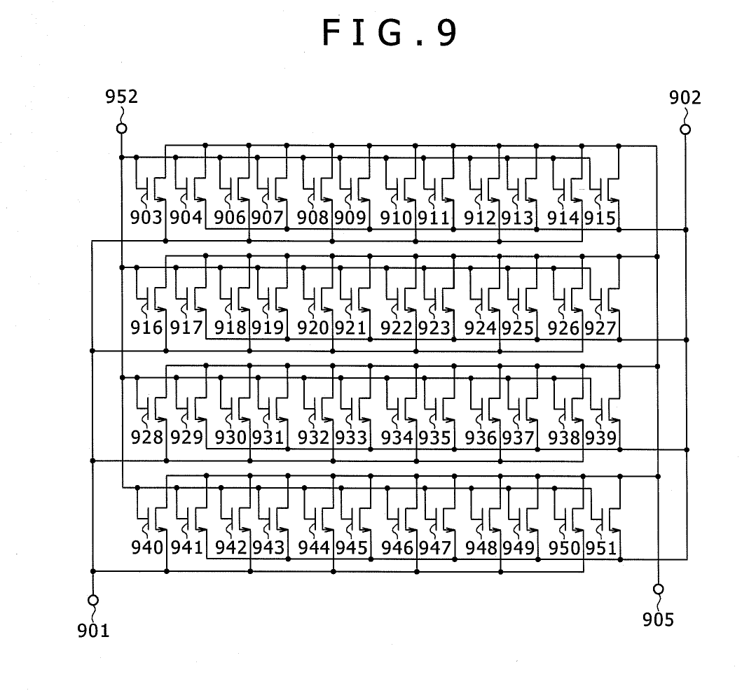

FIG. 8 illustrates the configuration of a second embodiment of the present invention.

The second embodiment has the same electrical connections as the first embodiment. Further, the second embodiment is similar to the first embodiment in that the sense MOS transistor element is divided into as many sections as possible.

The second embodiment differs from the first embodiment in that individual units 805 formed of a sense MOS transistor element section 803 and a main MOS transistor element section 804 are disposed point-symmetrically to each other. Hence, the center of gravity of all the disposed main MOS transistor elements and sense MOS transistor elements can be positioned at the center of the IC chip. This makes it possible to reduce variation. Further, the required area can be rendered smaller than that is required when the configuration depicted in FIG. 1 is used. Consequently, cost reduction can also be achieved.

What is claimed is:

1. A semiconductor device comprising:
a main MOS transistor element composed of two or more main MOS transistor element sections; and
a sense MOS transistor element composed of two or more sense MOS transistor element sections;
wherein unit cells each composed of a main MOS transistor element section paired with a sense MOS transistor element section are cyclically disposed in a plan layout;
wherein source and drain electrode terminals of the main MOS transistor element sections are electrically connected in parallel;
wherein source and drain electrode terminals of the sense MOS transistor element sections are electrically connected in parallel;
wherein gate electrode terminals of the main MOS transistor element sections and of the sense MOS transistor element sections are connected to a common gate drive power supply; and
wherein either the source electrode terminals or the drain electrode terminals of the main and sense MOS transistor element sections are connected to a common power supply or to a ground.

2. The semiconductor device according to claim 1, wherein the main MOS transistor element and the sense MOS transistor element are divided by the number of divisions that is determined by a size that is larger than the minimum size permitted by a manufacturing process of the sense MOS transistor element section and is smaller than two times the minimum size.

3. The semiconductor device according to claim 1, wherein one unit of the main MOS transistor element section and one unit of the sense MOS transistor element section are disposed nearest to each other.

4. The semiconductor device according to claim 1, wherein the main MOS transistor element and the sense MOS transistor element have the same center of gravity in the plan layout.

5. The semiconductor device according to claim 1, wherein the main MOS transistor element and the sense MOS transistor element are disposed on an SOI substrate; and wherein main MOS transistor element sections and the sense MOS transistor element sections are LDMOS transistors insulated by embedded oxide film.

6. The semiconductor device according to claim 1, wherein the unit cells are disposed in an arrangement of rows and columns.

7. The semiconductor device according to claim 6, wherein the unit cells within a row have a same orientation in the plan layout.

8. The semiconductor device according to claim 7, wherein the unit cells within a column have a same orientation in the plan layout as the unit cells within the row.

9. The semiconductor device according to claim 6, wherein each successive unit cell within a row is rotated 180° relative to the preceding unit cell of the row in the plan layout.

10. The semiconductor device according to claim 9, wherein the unit cells within a column have a same orientation in the plan layout.

11. The semiconductor device according to claim 6, wherein the unit cells are oriented such that the sense MOS transistor sections are disposed to form a number of columns that is one-half the number of columns of the unit cells.
